(19) United States
(12) Patent Application Publication
(10) Pub. No.: US 2005/0088894 A1
(43) Pub. Date: Apr. 28, 2005

(54) Auto-refresh multiple row activation

(76) Inventor: Paul Edward Brucke, Munich (DE)

Correspondence Address: Gero G. McClellan;MOSER, PATTERSON & SHERIDAN, L.L.P., Suite 1500, 3040 Post Oak Boulevard, Houston, TX, 77056-6582, US

(21) Appl. No.: 10/692,121

(22) Filed: Oct. 23, 2003

(51) Int. Cl. G11C 7/00

(52) U.S. Cl. 365/222

(57) ABSTRACT

The present invention generally provides methods and apparatus for activating rows for refreshing memory cells in the activated rows. In one embodiment, two or more rows of memory are activated in response to a single externally applied refresh command.

### BACKGROUND OF THE INVENTION

1. Field of the Invention

Embodiments of the present invention generally relate to dynamic random access memory (DRAM) devices and, more particularly, to self-refresh signals.

2. Description of the Related Art

Dynamic random access memory (DRAM) devices store data in memory elements that have an associated retention time. DRAM devices are referred to as dynamic because if the memory elements are not refreshed within the retention time, the data stored in the memory element may be lost. Accordingly, the memory elements are periodically refreshed.

Memory elements are typically organized in rows, and to refresh a DRAM every row must be activated. To activate a row, a row address is taken from an internal counter that tracks the row to be refreshed. The internal counter is incremented (or decremented) after each row activation, so that each row is activated sequentially. Once each row has been activated, the counter wraps.

Refreshing individual memory cells for an activated row involves receiving a signal level from a cell, amplifying the signal level to its full value (i.e., depending upon whether the cell contains a logic 1 or a logic 0) and providing the full signal level to the cell for storage. Accordingly, a row remains activated for a period of time during which each of the memory cells for that row are refreshed. This period of time may be referred to as the “row activation time”. Typically, the row activation time is defined by a timer, tRAS. The tRAS timer includes a delay element and a pulse generator. The delay element takes as input a signal from control logic, delays the signal by the required row activation time and then signals a pulse generator to create a pulse signaling the end of the row activation time and disabling a row activation signal.

Refreshing a DRAM is done in one of two ways, by issuing successive auto-refresh commands to the DRAM device or by putting the DRAM device in a self-refresh mode. In either case, rows are sequentially activated in the manner described above. Auto-refresh mode and self-refresh mode differ in that auto-refresh of memory is implemented by external control signals provided, e.g., by a processor or memory controller, whereas in self-refresh sequential activates are triggered by an oscillator. Accordingly, auto-refresh is typically used where the DRAM is likely to be accessed from an external source, e.g., a processor or memory controller. In contrast, self-refresh may be used while a computer system is in sleep mode where no external control inputs are provided, so that the DRAM is free to allocate the refresh cycles (within the maximum allowable refresh period between successive refreshes of a cell) to maximize efficiency, power management, etc.

As DRAMs continue to improve performance and increase in capacity, it is necessary to ensure their compatibility with external control sources (e.g., memory controllers and processors). For example, a given DRAM controller may be configured to issue 8K auto-refresh commands to refresh the entire device. However, as DRAM capacities grow, the number of rows to be refreshed increases and a single 8K auto-refresh command will be insufficient to refresh the entire device. Accordingly, it becomes necessary to replace or reconfigure the controller to issue more frequent auto-refresh commands, resulting in substantial costs to users of memory devices. Further, bus constraints may limit the number of auto-refresh commands that can be issued for a given retention time.

Therefore, what is needed is an apparatus and method for auto-refreshing memory devices.

### SUMMARY OF THE INVENTION

The present invention generally provides methods and apparatus for activating rows for refreshing memory cells in the activated rows.

One embodiment provides a method for activating a plurality of rows of a memory device. The method includes activating a predefined number of the rows in response to a single externally applied refresh command, wherein the predefined number is at least two of the plurality of rows.

Another embodiment for activating rows of memory cells in a memory device includes issuing auto-refresh commands at a first frequency, and, in response to the auto-refresh commands, activating rows of the memory at a second frequency greater than the first frequency.

Another embodiment provides a method of activating rows of memory to be refreshed. The method includes initiating a first row activation of a first row in a memory array; in response to the row activation signal, invoking a first timing circuit to issue a first refresh_end signal signaling an end of the first row activation after a period of time; in response to the refresh_end signal, invoking a second timing circuit to issue a refresh signal; and initiating a second row activation of a second row in the memory array in response to refresh signal.

Yet another embodiment provides a refresh timing circuit for a memory device. The circuit includes a first timer and a second timer. The first timer is configured to issue a Refresh_End signal a period of time, t1, after receiving each row activate signal from a control circuit. The second timer is configured to receive the Refresh_End signals from the first timer and issue a refresh signal a period of time, t2, after receiving each Refresh_End signal, wherein the refresh signal causes the control circuit to issue at least a second row activate signal.

Yet another embodiment provides an on-chip circuit for refreshing a memory device. The circuit includes a control circuit including a command line for receiving externally initiated refresh commands and a row activate output line for issuing row activate signals, wherein the control circuit is configured to issue a first row activate signal in response to receiving an externally initiated refresh command on the command line. The on-chip circuit further includes a first timer and a second timer. The first timer is coupled to the control circuit and is configured to receive each of the row activate commands from the control circuit and issue Refresh_End signals a period of time, t1, after receiving each row activate signal. The second timer is coupled to the control circuit and the first timer and is configured to receive the Refresh_End signals from the first timer and issue a refresh signal a period of time, t2, after receiving each Refresh_End signal, wherein the refresh signal causes the control circuit to issue at least a second row activate signal.

Still another embodiment provides an apparatus for activating rows of memory in a memory device. The apparatus includes a controller configured to issue auto-refresh commands; a control circuit configured to issue at least sequential row activate signals to activate the rows of memory in the memory device; wherein a first row activate signal is issued in response to receiving a first auto-refresh command; a first timer configured to receive each of the row activate signals from the control circuit and issue Refresh_End signals a period of time, t1, after receiving each row activate signal; and a second timer configured to receive the Refresh_End signals from the first timer and issue a refresh signal a period of time, t2, after receiving each Refresh_End signal, wherein the refresh signal causes the control circuit to issue at least a second row activate signal to the first timer.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a high level schematic of a memory system.

FIG. 2 is a schematic showing one embodiment of a refresh circuit coupled to a command decoder.

FIG. 3 is a schematic showing one embodiment of a refresh circuit.

FIG. 4 is a state table describing one embodiment of an auto-refresh cycle in which two memory rows are activated.

FIG. 5 is a timing diagram corresponding to the Table of FIG. 4.

### DETAILED DESCRIPTION OF THE PREFERRED EMBODIMENTS

The present invention generally provides methods and apparatus for activating rows for refreshing memory cells in the activated rows. In one embodiment, two or more rows of memory are activated in response to a single externally applied refresh command. Although reference is made specifically to DRAM, the present invention applies to any volatile memory that requires periodic refreshing of stored logic levels (e.g., as defined by the stored charge of a capacitor).

Embodiments of the invention provide for an externally applied refresh command to activate a predefined number of rows in a memory. For example, in one embodiment, a controller issues Auto-Refresh commands each of which result in sequentially activating two rows. In this way, a controller (or other external source of refresh commands) may refresh an entire memory device with less total commands than the total number of rows in the memory device. In a particular embodiment, a first timer receives a Row_Active signal and delays the output of a Refresh_End to give the first row activation enough time to refresh a first row. A second timer is configured to wait a sufficient amount of time after refresh of the first row to allow for precharge of a second row and then signals for the start of another row activate. In one embodiment, the second timer is disabled after the second row activate, thereby preventing the second timer from issuing another row activate.

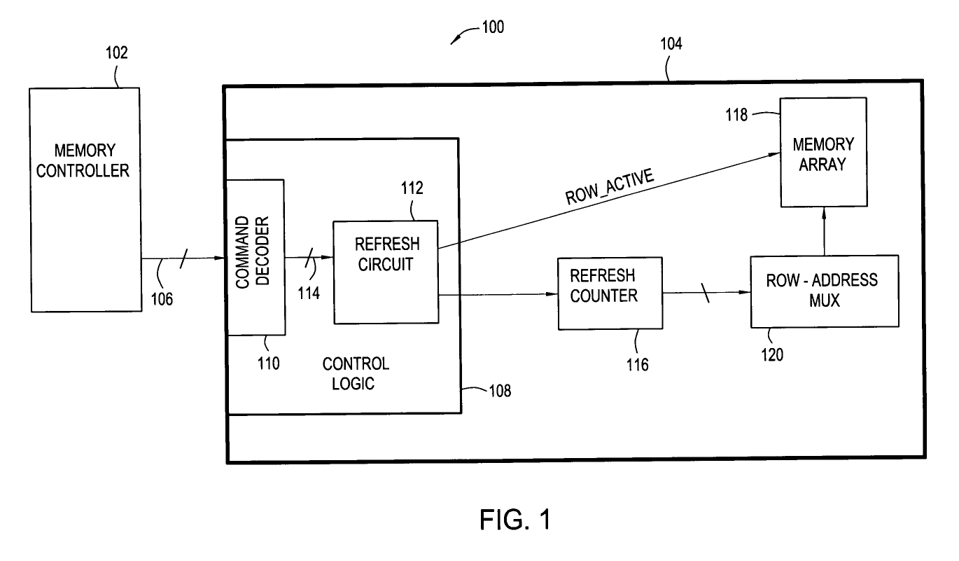

Referring now to FIG. 1, a memory system 100 is shown. The memory system includes an external signal source 102 and a memory device 104 (e.g., a DRAM) having one or more memory arrays 118 (one shown). Illustratively, the external signal source 102 is shown as a memory controller. However, more generally, the external signal source 102 is representative of any device configured to issue commands to the memory device 104, including at least an auto-refresh command. For example, in another embodiment, the external signal source 102 is a processor configured to issue at least an auto-refresh command to the memory device 104. The external signal source 104 may also be configured to issue other known or unknown commands, such as self-refresh commands. As defined herein an auto-refresh command is a command which causes the memory device 104 to successively activate a predefined number (at least two) of rows of the memory array 118 in response to each auto-refresh command. A self-refresh command is a command which causes the memory device 104 to enter a self-refresh mode in which the device 104 manages the activating (and refreshing, generally) of its memory arrays without further external inputs.

Illustratively, commands are propagated from the memory controller 102 to control logic 108 of the memory device 104 via a bus 106. The commands are received and decoded by a command decoder 110 of the control logic 108. A refresh circuit 112 is coupled to the command decoder 110 via a bus 114 and is configured to issue signals needed to refresh memory cells of the array 118. To this end, the refresh circuit 112 is coupled to the memory array and a refresh counter 116. The refresh counter 116 is configured to increment a count after each refresh cycle. A row-address multiplexor 120 decodes this count to generate a row address.

It should be understood that the memory system 100 of FIG. 1 is shown in a simplified form and, in practice, may include a number of other circuits, including, for example, column decoders, bank selection logic, drivers, sense amplifiers, I/O circuitry, etc. In addition to the command bus 106, the memory controller 102 may be coupled to the memory device 104 via address and control lines, as is known in the art. In addition, a number of memory elements may be implemented in plurality, although shown as singular in FIG. 1. For example, the memory device may have a plurality of memory arrays which make up banks of memory. In any case, the memory system 100 of FIG. 1 is merely illustrative and a variety of different embodiments are contemplated.

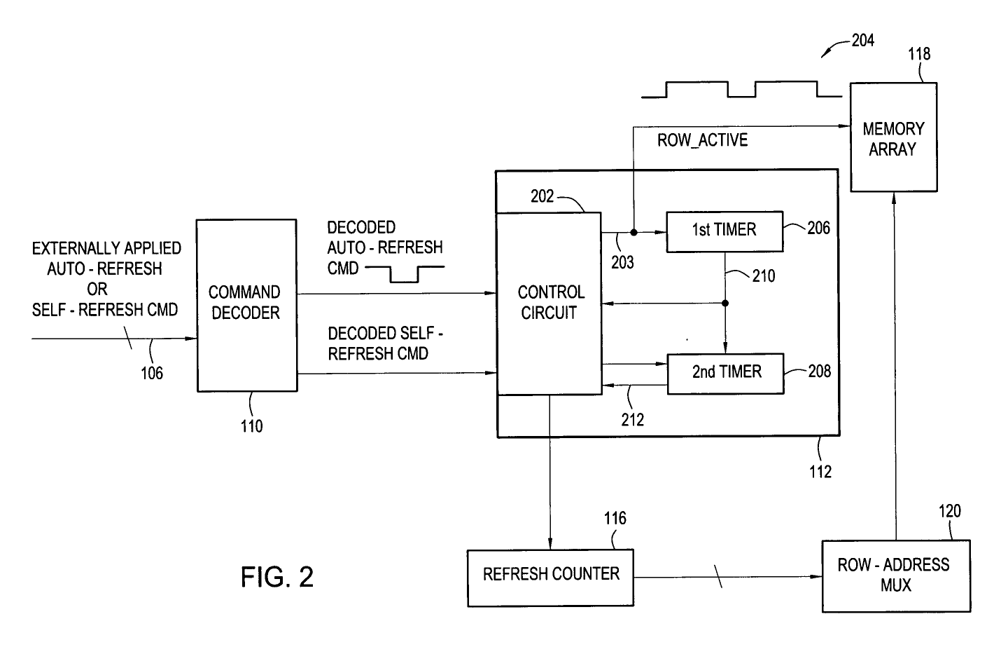

Referring now to FIG. 2, one embodiment of the command decoder 110 and refresh circuit 112 is shown. Illustratively, the command decoder 110 takes as inputs (via the command bus 106) an externally applied auto-refresh command and an externally applied self-refresh command. Each of the commands may be supplied by the memory controller 102 via the bus 106 (shown in FIG. 1). Further, each of the commands input to the command decoder 110 are decoded and output to a control circuit 202 of the refresh circuit 112 via the bus 114 (shown in FIG. 1). The control circuit 202 is configured to issue Row_Activate signals to the memory array 118 via a line 206 and Row_Increment signals to the refresh counter 116 via a line 208.

As noted, the refresh circuit 112.(and more particularly, the control circuit 202) is configured to successively activate two or more rows of the memory array 118 in response to a single externally applied auto-refresh command. Row activation is illustratively achieved by pulling a Row_Activate signal 204 HIGH. The Row_Activate signal 204 is propagated on a line 203 to the memory array 118. Illustratively, the duration of each refresh cycle (i.e., the activation period for a row as defined by a HIGH Row_Activate signal) is controlled by a first timer 206. In one embodiment, a number of subsequent refresh cycles is controlled by a second timer 208.

The first and second timers are both coupled to the control circuit 202. Generally, the first timer 206 is configured to terminate a first row active (represented by a first HIGH of the Row_Active signal 204) by issuing a Refresh_End signal on an output line 210 coupled to both the control circuit 202 and the second timer 208. Accordingly, the Refresh_End signal is provided to the second timer 208 and causes the second timer 208 to produce an output (on a line 212) resulting in at least a second row active (represented by a second HIGH of the Row_Active signal 204). As used herein, the length of time of a “row active” (i.e., the duration of a HIGH of the Row_Active signal 204) is synonymous with “refresh cycle”, since the time that a row remains activated is determined by the time needed for refreshing the row.

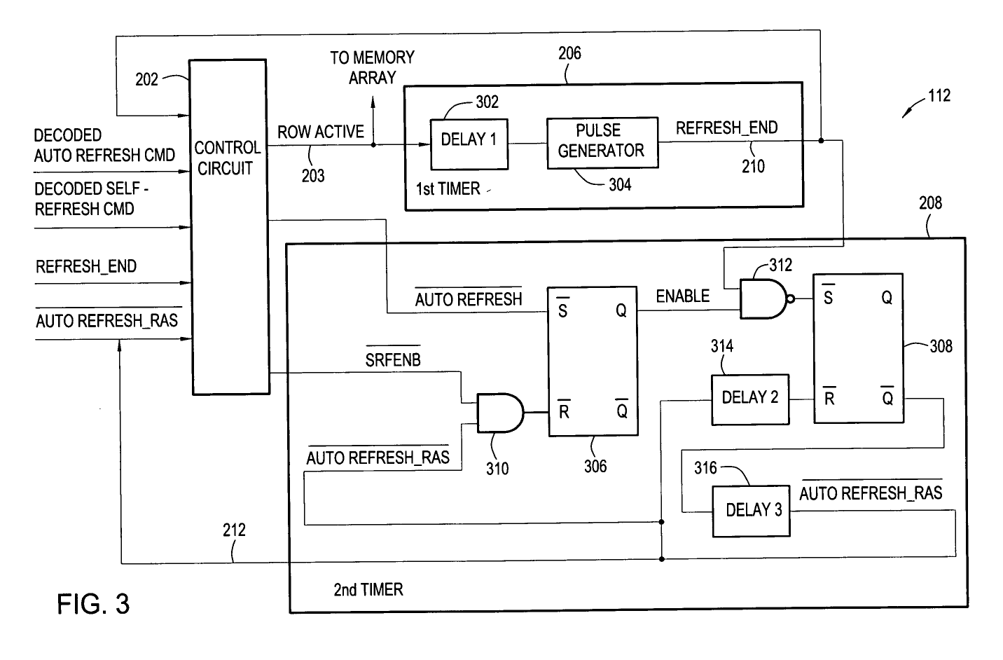

Referring now to FIG. 3, one embodiment of the refresh circuit 112 is shown. Illustratively, the first timer 206 includes a delay circuit 302 and a pulse generator 304. One purpose of the first timer 206 is to control the duration of refresh cycles by generating a Refresh_End signaling the control circuit 202 to pull the Row_Active signal LOW. The delay circuit 302 is coupled at its input to the control circuit 202 via the Row_Active line 203, and is coupled at its output to the pulse generator 304. The pulse generator 304 is coupled at its output to the control circuit 202 and the second timer 208 via the Refresh_End output line 210. In one embodiment, the first timer 206 is a conventional tRAS timer which controls the duration of each row activation. In the depicted embodiment, the Refresh_End signal generated by first timer 206 also signals the second timer 208.

In one embodiment, the second timer 208 is configured to control the duration of a precharge and signal the control circuit 202 to cause at least one subsequent row activation (i.e., pull the Row_Active signal HIGH some period of time after the end of an immediately preceding Row_Active HIGH). Illustratively, the second timer 208 includes a first latch 306 and a second latch 308. Illustratively, both latches are S-R latches. In the depicted embodiment, the first latch 306 is set (Q=HIGH) in response to an active low AutoRefresh signal which pulls an Enable signal to HIGH, thereby enabling the second latch 308. The second latch 308 is then set (/Q=LOW) in response to the Refresh_End singal, which is NAND'd with the Enable signal via a NAND gate 312. When set, the output of the second latch 308 initiates the active low AutoRefresh_RAS signal which initiates a second refresh cycle via the control circuit 202. The active low AutoRefresh_RAS signal is delayed by a delay circuit 316 configured to provide sufficient precharge time between refresh cycles.

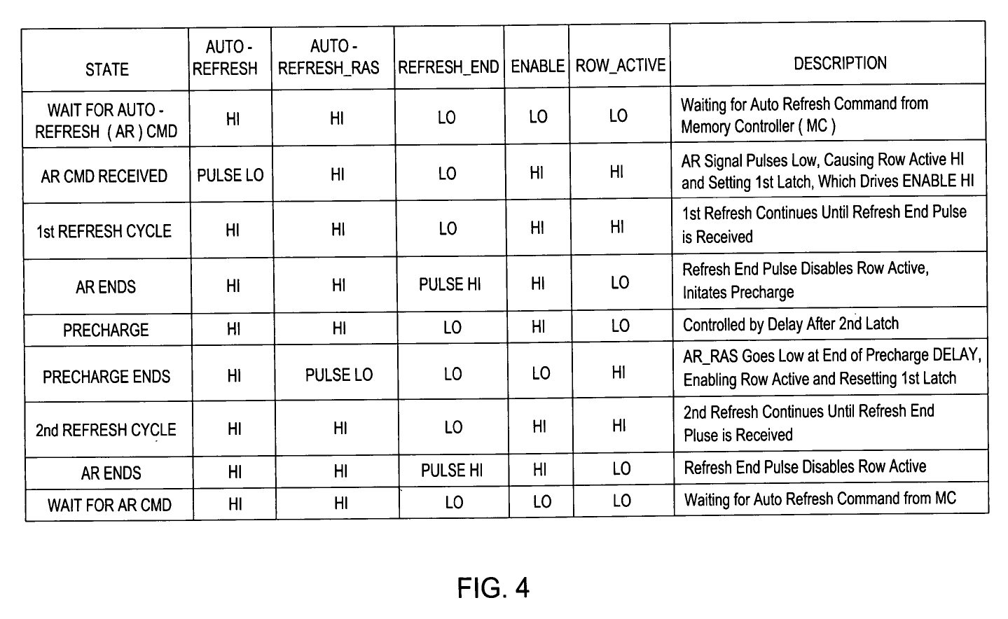

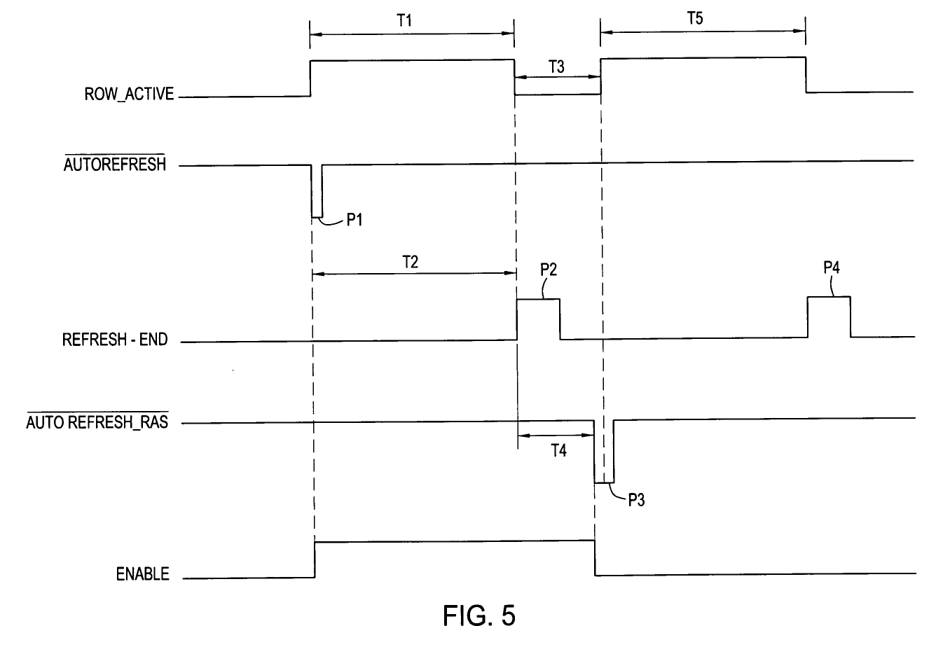

The operation of the refresh circuit 112 is now described with respect to FIGS. 3-5, where FIG. 4 is a state table and FIG. 5 is a timing diagram. Initially, the active low signals (i.e., AutoRefresh and AutoRefresh_RAS) are HIGH and the active high signals (i.e., Refresh_End, Enable and Row_Active) are LOW. A decoded Auto-Refresh command to the control circuit 202 starts a refresh cycle (i.e., Row_Active HIGH, T1, on the line 203) and creates the active low pulse AutoRefresh, P1. The Row_Active HIGH activates a row of the memory array 118 and is also input to, and delayed by, the delay circuit 302. The duration of the delay, T2, implemented by the delay circuit 302 is determined according to the length of time needed to refresh the activated row of the memory array. At the expiration of the delay, T2, the pulse generator 304 is signaled to create a HIGH pulse Refresh_End, P2, on the output line 210. HIGH pulse Refresh_End signals the control circuit 202 to terminate the first Row_Active and increment the refresh counter 116 (shown in FIGS. 1-2). Further, the Row_Active going low initiates a precharge period, T3.

As previously described, the active low pulse AutoRefresh, P1, sets the first S-R latch 306, thereby pulling the Enable signal HIGH. Pulling the Enable signal HIGH, in turn, enables the HIGH pulse Refresh_End from the first timer 206 to set the second S-R latch 308. When set, the second latch 308 outputs the active low AutoRefresh_RAS which is input to the control circuit 202 to initiate a second refresh cycle. However, the AutoRefresh_RAS is delayed by the delay circuit 316 before being input to the input to the control circuit 202. Accordingly, the falling edge of the active low signal AutoRefresh_RAS is not sensed until a period of time, T4, after the rising edge of the HIGH pulse Refresh_End, P2, allowing for the precharge period T3.

In the present embodiment, the AutoRefresh_RAS signal is a multifunctional signal. Specifically, the AutoRefresh_RAS signal going LOW signals the control circuit 202 to perform a second refresh cycle, i.e., pull Row_Active HIGH and increment the counter 116. The Row_Active HIGH is held HIGH for a period, T5, and then terminated by the pulse HIGH Refresh_End, P4, from the pulse generator 304. The AutoRefresh_RAS is also fed back to both latches 306, 308 to reset them. The reset of the first latch 306 disables the next Refresh_End pulse from resulting in another row active being signaled by the second timer 208. Resetting the second latch 308 after a delay implemented by the delay circuit 314 defines the width of the low pulse AutoRefresh_RAS, P3.

In one embodiment, the second timer 208 may also be disabled by pulling a self-refresh enable signal (SRFENB) LOW, thereby keeping the output of the gate 310 LOW. In particular, it may be desirable to disable the second timer 208 and prevent it from being used during a Self-Refresh.

As noted, it is contemplated that the refresh circuit 112 may be configured to perform any number of successive row actives between each externally supplied auto-refresh command. Accordingly, one skilled in the art will recognize that the refresh circuit 112 may be readily modified to allow more than two successive row actives (i.e., refresh cycles).

While the foregoing is directed to embodiments of the present invention, other and further embodiments of the invention may be devised without departing from the basic scope thereof, and the scope thereof is determined by the claims that follow.

1. A method for activating a plurality of rows of a memory device, the method comprising:
activating a predefined number of the rows in response to a single externally applied refresh command, wherein the predefined number is at least two of the plurality of rows.

2. The method of claim 1, wherein the predefined number is less than all of the plurality of rows.

3. The method of claim 1, wherein the externally applied refresh command is an auto-refresh command.

4. The method of claim 1, wherein the externally applied refresh command is an auto-refresh command issued by a memory controller.

5. The method of claim 1, wherein activating the predefined number of the rows comprises sequentially activating the predefined number of the rows.

6. The method of claim 1, wherein activating the predefined number of the rows is done without an oscillator internal to the memory.

7. The method of claim 1, wherein the externally applied refresh command is an auto-refresh command and wherein the predefined number is between two and four.

8. A method for activating rows of memory cells in a memory device comprising N rows of memory cells, the method comprising:
issuing auto-refresh commands at a first frequency; and
in response to the auto-refresh commands, activating rows of the memory at a second frequency greater than the first frequency.

9. The method of claim 8, wherein the first frequency is determined by the time needed to refresh a number of the rows at the second frequency.

10. The method of claim 8, wherein the auto-refresh commands are issued by a memory controller.

11. The method of claim 8, further comprising issuing a self-refresh command to place the memory device in a self-refresh mode.

12. The method of claim 8, further comprising, in response to each auto refresh command, activating a predetermined number of rows of memory, the predetermined number being greater than two.

13. A method of activating rows of memory to be refreshed, comprising:
initiating a first row activation of a first row in a memory array;
in response to the row activation signal, invoking a first timing circuit to issue a first refresh_end signal signaling an end of the first row activation after a period of time;
in response to the refresh_end signal, invoking a second timing circuit to issue a refresh signal; and
initiating a second row activation of a second row in the memory array in response to refresh signal.

14. The method of claim 13, further comprising disabling the second timer after the refresh signal is issued.

15. The method of claim 13, further comprising disabling the second timer during self-refresh of the rows of memory.

16. The method of claim 13, further comprising in response to the second row activation signal, invoking the first timing circuit to issue second refresh_end signal signaling an end of the second row activation after the period of time.

17. A refresh timing circuit for a memory device, comprising:
a first timer configured to issue a Refresh_End signal a period of time, t1, after receiving each row activate signal from a control circuit; and
a second timer configured to receive the Refresh_End signals from the first timer and issue a refresh signal a period of time, t2, after receiving each Refresh_End signal, wherein the refresh signal causes the control circuit to issue at least a second row activate signal.

18. The circuit of claim 17, wherein the first row activate signal is received by the first timer in response to an externally applied auto-refresh command being received.

19. The circuit of claim 17, wherein the device is a memory array.

20. The circuit of claim 17, wherein the second timing circuit comprises a latch configured to output the refresh signal when the latch is set and a feedback line on which the refresh signal is propagated back to the latch to reset the latch and prevent a subsequent Refresh_End signal from causing issuance of a subsequent refresh signal.

21. A on-chip circuit for refreshing a memory device, comprising:
a control circuit comprising:
a command line for receiving externally initiated refresh commands; and
a row activate output line for issuing row activate signals, wherein the control circuit is configured to issue a first row activate signal in response to receiving an externally initiated refresh command on the command line;
a first timer coupled to the control circuit and configured to receive each of the row activate commands from the control circuit and issue Refresh_End signals a period of time, t1, after receiving each row activate signal; and
a second timer coupled to the control circuit and the first timer and configured to receive the Refresh_End signals from the first timer and issue a refresh signal a period of time, t2, after receiving each Refresh_End signal, wherein the refresh signal causes the control circuit to issue at least a second row activate signal.

22. The circuit of claim 21, wherein the command line is an auto-refresh command line.

23. The circuit of claim 21, wherein the second timer is configured to issue a disabling signal to disable the second timer.

24. The circuit of claim 23, wherein the disabling signal is the refresh signal.

25. An apparatus for activating rows of memory in a memory device, comprising:
a controller configured to issue auto-refresh commands;
a control circuit configured to issue at least sequential row activate signals to activate the rows of memory in the memory device; wherein a first row activate signal is issued in response to receiving a first auto-refresh command;
a first timer configured to receive each of the row activate signals from the control circuit and issue Refresh_End signals a period of time, t1, after receiving each row activate signal; and
a second timer configured to receive the Refresh_End signals from the first timer and issue a refresh signal a period of time, t2, after receiving each Refresh_End signal, wherein the refresh signal causes the control circuit to issue at least a second row activate signal to the first timer.

26. The apparatus of claim 25, wherein the control circuit, the first timer and the second timer are disposed on the memory device.

27. The apparatus of claim 25, further comprising a disabling circuit configured to disable the second timer while the memory device is in self-refresh mode.
